(19) United States
(12) Patent Application Publication
(10) Pub. No.: US 2023/0265582 A1
(43) Pub. Date: Aug. 24, 2023

(54) SYSTEMS AND METHODS FOR PROCESSING THE SURFACE OF AN EPITAXIALLY GROWN SILICON FILM USING A RADICAL SPECIES

(71) Applicant: ASM IP Holding B.V., Almere (NL)

(72) Inventors: Gregory Deye, Phoenix, AZ (US); Yen Chun Fu, Tempe, AZ (US); Arun Murali, Tempe, AZ (US)

(21) Appl. No.: 18/110,403

(22) Filed: Feb. 16, 2023

Related U.S. Application Data
(60) Provisional application No. 63/312,256, filed on Feb. 21, 2022.

(51) Int. Cl. C30B 33/08; C30B 25/18; C30B 29/06

(52) U.S. Cl. CPC C30B 33/08; C30B 25/186; C30B 29/06

(57) ABSTRACT

A method of processing a surface of an epitaxially grown silicon film includes using a radical species to remove random surface terminations from the surface of the epitaxially grown silicon film and to generate a substantially uniform distribution of surface terminations. Reaction systems for performing such a method, and epitaxially grown films prepared using such a method, also are provided.

### CROSS-REFERENCE TO RELATED APPLICATIONS

This application is a nonprovisional of, and claims priority to and the benefit of, U.S. Provisional Patent Application No. 63/312,256, filed Feb. 21, 2022 and entitled “SYSTEMS AND METHODS FOR PROCESSING THE SURFACE OF AN EPITAXIALLY GROWN SILICON FILM USING A RADICAL SPECIES,” which is hereby incorporated by reference herein.

### FIELD OF INVENTION

The present disclosure relates generally to processing the surface of a silicon film using a radical species.

### BACKGROUND OF THE DISCLOSURE

During epitaxial growth of a silicon film on a surface, the surface is exposed to precursors which are at the correct temperature, pressure, and partial pressure to form a periodic lattice structure. It would be desirable to further improve the quality of the epitaxially grown silicon film's surface, for example so as to improve the quality of film(s) that are subsequently deposited onto that surface and/or to improve the quality of devices that include the epitaxially grown silicon film.

### SUMMARY OF THE DISCLOSURE

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

Some examples herein provide a method of processing a surface of an epitaxially grown silicon film. The method may include using a first radical species to remove random surface terminations from the surface of the epitaxially grown silicon film and to generate a substantially uniform distribution of surface terminations.

In some examples, the first radical species reacts preferentially with the random surface terminations as compared to a bulk of the epitaxially grown silicon film.

In some examples, the first radical species includes a hydrogen radical, and the substantially uniform distribution of surface terminations includes Si—H moieties. In other examples, the first radical species includes a chlorine radical, and the substantially uniform distribution of surface terminations includes Si—Cl moieties. In other examples, the first radical species includes a fluorine radical, and the substantially uniform distribution of surface terminations includes Si—F moieties. In other examples, the first radical species includes a nitrogen radical, and the substantially uniform distribution of surface terminations includes Si—N moieties.

In some examples, the random surface terminations include combinations of two or more of silicon moieties, hydrogen moieties, chlorine moieties, phosphorous moieties, and arsenic moieties.

In some examples, the epitaxially grown silicon film is doped.

In some examples, the epitaxially grown silicon film is disposed on a silicon wafer.

In some examples, the epitaxially grown silicon film is vertically oriented. In some examples, the epitaxially grown silicon film is horizontally oriented.

In some examples, the first radical species forms covalent bonds with the surface.

In some examples, the method includes using a second radical species to clean a wafer before forming the epitaxially grown silicon film on the wafer. In some examples, the wafer is located within the same chamber during use of the second radical species to clean the wafer and during use of the radical species to remove the random surface terminations from the surface of the epitaxially grown silicon film.

In some examples, the method includes forming the epitaxially grown silicon film on the wafer.

Some examples herein provide a film deposition method. The method may include, within a first chamber, using a first radical species to remove an oxide from a surface of a wafer. The method may include transferring the wafer to a second chamber. The method may include, within a second chamber, epitaxially growing a silicon film on the surface from which the oxide was removed. The method may include transferring the wafer, having the epitaxially grown silicon film thereon, back to the first chamber. The method may include, within the first chamber, using a second radical species to remove random surface terminations from the surface of the epitaxially grown silicon film and to generate a substantially uniform distribution of surface terminations.

In some examples, the transferring operations are performed using robotics. In some examples, the robotics transfer the wafer from the first chamber to the second chamber through a transfer chamber, and from the second chamber to the first chamber through the transfer chamber.

In some examples, the second radical species reacts preferentially with the random surface terminations as compared to a bulk of the epitaxially grown silicon film.

In some examples, the second radical species includes a hydrogen radical, and wherein the substantially uniform distribution of surface terminations includes Si—H moieties. In other examples, the second radical species includes a chlorine radical, and the substantially uniform distribution of surface terminations includes Si—Cl moieties. In other examples, the second radical species includes a fluorine radical, and the substantially uniform distribution of surface terminations includes Si—F moieties. In other examples, the second radical species includes a nitrogen radical, and the substantially uniform distribution of surface terminations includes Si—N moieties. In other examples, the random surface terminations include combinations of two or more of silicon moieties, hydrogen moieties, chlorine moieties, phosphorous moieties, and arsenic moieties.

In some examples, the epitaxially grown silicon film is doped.

In some examples, the epitaxially grown silicon film is disposed on a silicon wafer.

In some examples, the epitaxially grown silicon film is vertically oriented. In some examples, the epitaxially grown silicon film is horizontally oriented.

In some examples, the first radical species includes a hydrogen radical, a fluorine radical, a nitrogen radical, or a chlorine radical.

In some examples, the second radical species forms covalent bonds with the surface.

Some examples herein provide a system for processing a surface of an epitaxially grown silicon film. The system may include a reaction chamber configured to hold a wafer having an epitaxially grown silicon film thereon. The system may include a remote plasma unit. The system may include a precursor source unit. The system may include a controller configured to cause the precursor source unit to provide a first radical species precursor to the remote plasma unit; cause the remote plasma unit to generate a first radical species using the first radical species precursor; and cause the first radical species to flow into the reaction chamber to use the first radical species to remove random surface terminations from the surface of the epitaxially grown silicon film and to generate a substantially uniform distribution of surface terminations.

In some examples, the first radical species reacts preferentially with the random surface terminations as compared to a bulk of the silicon film.

In some examples, the first radical species includes a hydrogen radical, and the substantially uniform distribution of surface terminations includes Si—H moieties. In other examples, the first radical species includes a chlorine radical, and the substantially uniform distribution of surface terminations includes Si—Cl moieties. In other examples, the first radical species includes a fluorine radical, and the substantially uniform distribution of surface terminations includes Si—F moieties. In other examples, the first radical species includes a nitrogen radical, and the substantially uniform distribution of surface terminations includes Si—N moieties.

In some examples, the random surface terminations include combinations of two or more of silicon moieties, hydrogen moieties, chlorine moieties, phosphorous moieties, and arsenic moieties.

In some examples, the epitaxially grown silicon film is doped.

In some examples, the wafer includes silicon.

In some examples, the epitaxially grown silicon film is vertically oriented.

In some examples, the epitaxially grown silicon film is horizontally oriented.

In some examples, the radical species forms covalent bonds with the surface.

In some examples, the remote plasma unit further is configured to use a second radical species to clean the wafer before forming the epitaxially grown silicon film on the wafer.

In some examples, the semiconductor wafer is located within the same chamber during use of the second radical species to clean the wafer and during use of the first radical species to remove the random surface terminations from the surface of the epitaxially grown silicon film.

Some examples herein provide an epitaxially grown silicon film processed using operations including using a radical species to remove random surface terminations from the surface of the epitaxially grown silicon film and to generate a substantially uniform distribution of surface terminations.

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

All of these embodiments are intended to be within the scope of the invention herein disclosed. These and other embodiments will become readily apparent to those skilled in the art from the following detailed description of certain embodiments having reference to the attached figures, the invention not being limited to any particular embodiment(s) disclosed.

### BRIEF DESCRIPTION OF THE DRAWING FIGURES

While the specification concludes with claims particularly pointing out and distinctly claiming what are regarded as embodiments of the invention, the advantages of embodiments of the disclosure may be more readily ascertained from the description of certain examples of the embodiments of the disclosure when read in conjunction with the accompanying drawings, in which:

FIGS. 1A-1F schematically illustrate cross-sections of example structures and operations during a method for processing the surface of an epitaxially grown silicon film using a radical species.

FIG. 2 schematically illustrates examples of surface terminations on an epitaxially grown silicon film.

FIGS. 3A-3B schematically illustrate example films disposed on epitaxially grown silicon films respectively without, and with, the present processing.

FIG. 4 schematically illustrates components of an example system for processing the surface of an epitaxially grown silicon film using a radical species.

FIG. 5 schematically illustrates components of an example system for depositing an epitaxially grown silicon film and for processing the surface of that film using a radical species.

FIG. 6 illustrates a flow of operations in an example method for processing the surface of an epitaxially grown silicon film using a radical species.

The illustrations presented herein are not meant to be actual views of any particular material, structure, or device, but are merely idealized representations that are used to describe embodiments of the disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

A number of example materials are given throughout the embodiments of the current disclosure, it should be noted that the chemical formulas given for each of the materials should not be construed as limiting and that the non-limiting example materials given should not be limited by a given example stoichiometry.

The terms “substantially,” “approximately,” and “about” used throughout this specification are used to describe and account for small fluctuations, such as due to variations in processing. For example, they may refer to less than or equal to ±10%, such as less than or equal to ±5%, such as less than or equal to ±2%, such as less than or equal to ±1%, such as less than or equal to ±0.5%, such as less than or equal to ±0.2%, such as less than or equal to ±0.1%, such as less than or equal to ±0.05%.

The term “silicon film” is intended to encompass films that include silicon, and that optionally may include one or more components other than silicon. For example, a “silicon film” may include silicon as well as a dopant, and optionally may consist essentially of the silicon and the dopant. Nonlimiting examples of dopants include phosphorous (P) and arsenic (As).

The surface of an epitaxially grown silicon film affects the electrical performance output of a device that includes such film. However, as recognized by the present inventor, the quality of such surface previously has not previously been well controlled. For example, after epitaxial growth of a silicon film is complete, the precursors are turned off and the reactor settings are changed, e.g., to appropriate wafer transfer conditions. As recognized by the present inventor, turning off inbound precursors leaves random surface terminations at the growth surface. For example, surface terminations include chemicals that are either partially or fully decomposed to a lower energy stage that is bound in some form to the film. Surface terminations may include, for example, fractions of the epitaxy precursors which are physisorbed or chemisorbed to the surface, or even hydrogenated silicon. Such surface terminations may be covalently bonded to the surface at random locations, resulting in random chemical identities of the surface. Such surface terminations may include, illustratively, Si-dopant moieties (which may be in their hydrogenated state) and/or higher energy Si—Cl moieties that are randomly mixed with lower energy Si—H moieties. Additionally, or alternatively, the random surface terminations may include different crystallographic orientations, such as a mixture of the higher energy silicon 100 and the lower energy silicon 111. Such a mixture of surface terminations on the film surface may detrimentally increase the film's propensity to oxidize. Additionally, or alternatively, such a mixture of surface terminations on the film surface may provide charge trap states that detrimentally and randomly affect the film's electrical characteristics in different regions.

It would be desirable to reduce or substantially eliminate the random terminations on the surface of an epitaxially grown silicon film, for example so as to reduce the film's propensity to oxidize and/or to reduce charge trap states. As recognized by the present inventor, reaction of the surface with radicals may be used to replace random surface terminations, such as Si-dopant and/or Si—Cl moieties, with a relatively uniform distribution of lower-energy surface terminations. The resulting surface may be more resistant to oxidation and/or formation of charge trap states than the random terminations, and thus may result in a surface with improved electrical qualities such as improved charge carrier mobility.

As provided herein, the surface of the epitaxially grown silicon may be processed using radical chemistry that otherwise has been used as a “preclean” step to remove oxide from the surface of a wafer before epitaxially growing a silicon film thereon. In one nonlimiting example, the surface of the epitaxially grown silicon film is hydrogenated using hydrogen radicals. Such radical-based hydrogenation may be performed at relatively low temperatures, e.g., about 200° C. or less, and may result in reduction or substantial removal of any surface terminations other than Si—H moieties as well as any higher-energy surfaces such as exposed silicon crystal planes. Accordingly, such radical-based hydrogenation may provide a relatively even distribution of Si—H moieties across a relatively low-energy silicon surface. Accordingly, it is expected that the film surface resulting from such processing may have a reduced number of defects and charge-trap states, may have a lower oxidation rate, and/or may have higher charge carrier mobility than a surface which has not been processed as such.

It is also expected that radical species besides hydrogen suitably may be used, and may provide a similarly low-energy surface including a relatively uniform distribution of surface terminations including the reaction products of such radicals and silicon atoms at the surface. For example, uniform hydrogen termination allows for improved robustness to oxidation and also does not degrade electrical performance. Alternatively, the halogen-based radicals F and Cl may be used similarly as hydrogen radicals to uniformly terminate the surface with halogen moieties (e.g., Si—Cl or Si—F). The resulting Si-halogen moieties may be dipoles in which electron density is drawn away from the silicon, and thus may be expected to shift the work function of the silicon film relative to a surface with uniform Si—H moieties. As another alternative, the nitrogen radical NH₂ may be used to uniformly terminate the surface with nitrogen (Si—N) moieties. The resulting Si—N moieties may be dipoles in which electron density is drawn away from the nitrogen, and thus may be expected to shift the work function of the silicon film relative to a surface with uniform Si—H terminations and in a direction opposite that of the uniform Si-halogen terminations. In some examples, the surface terminations consist substantially of, or consist essentially of, the same type of moiety.

Note that attempting to hydrogenate the surface of the epitaxially grown silicon film using a baking procedure is not expected to be successful. For example, baking the epitaxially grown silicon film at temperatures exceeding 700° C. is expected to increase the likelihood that any dopant in the silicon film may undesirably precipitate or diffuse into undesired areas, such as a silicon channel disposed below or adjacent to the silicon film, degrading the device's electrical performance. Moreover, baking is prohibitive in some applications owing to the thermal budget specific to certain patterned wafers; where temperatures in excess of 700° C. would otherwise promote silicon reflow and ultimate reshaping of critical structures.

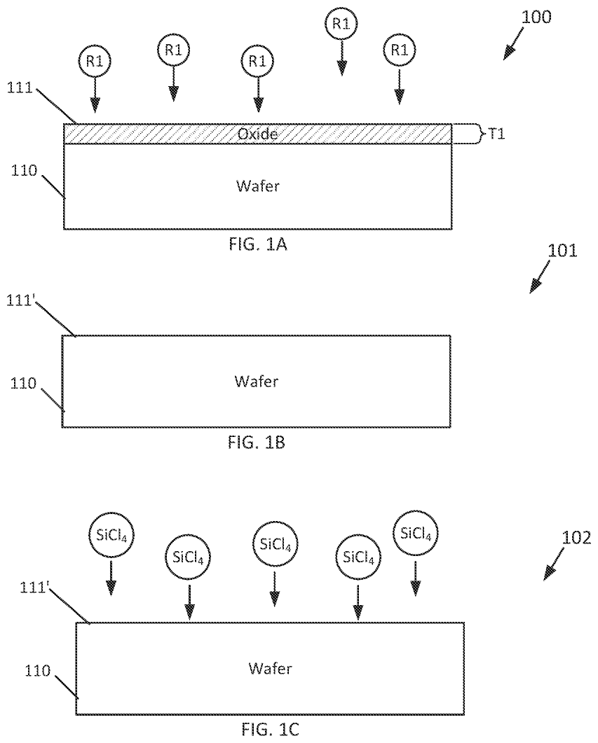

FIGS. 1A-1F schematically illustrate cross-sections of example structures and operations during a method for processing the surface of an epitaxially grown silicon film using a radical species. Some examples optionally include preparing the epitaxially grown film. For example, at operation 100 illustrated in FIG. 1A, a structure including wafer 110 having an oxide at its surface 111 is exposed to a first radical species R1. The oxide may have a thickness T1, which in some examples may be in the range of about 0.1 nm to about 6 nm. First radical species R1 removes the oxide from the surface 111 of the wafer 110. The first radical species R1 may react with the first material it comes into contact with, namely the oxide wafer 110, so as to remove some or substantially all of the oxide from surface 111. The first radical species R1 may form covalent bonds with the oxide. At least some of the products of such reactions may be gaseous.

At operation 101 illustrated in FIG. 1B, the first radical species R1 and any gaseous reaction products then are removed, for example using a flow of an inert gas. As illustrated in FIG. 1B, following use of first radical species R1, oxide is removed which exposes modified surface 111′. At operation 102 illustrated in FIG. 1C, silicon is epitaxially grown on surface 111′, e.g., in a different reaction chamber than in which operations 100 and 101 are performed. For example, surface 111′ may be exposed to one or more precursors which are at the correct temperature, pressure, and partial pressure to form a periodic lattice structure. In the nonlimiting example illustrated in FIG. 1C, the precursor(s) include SiCl₄, although it will be appreciated that any other precursor(s) suitably may be used such as dichlorosilane, silane, disilane, or trisilane. Additionally, the precursors optionally may include a precursor of a dopant that is being included in the silicon film. At operation 103 illustrated in FIG. 1D, the precursor(s) are removed, for example using a flow of an inert gas. As illustrated in FIG. 1D, the resulting epitaxially grown silicon film 120, 130 has a thickness T2.

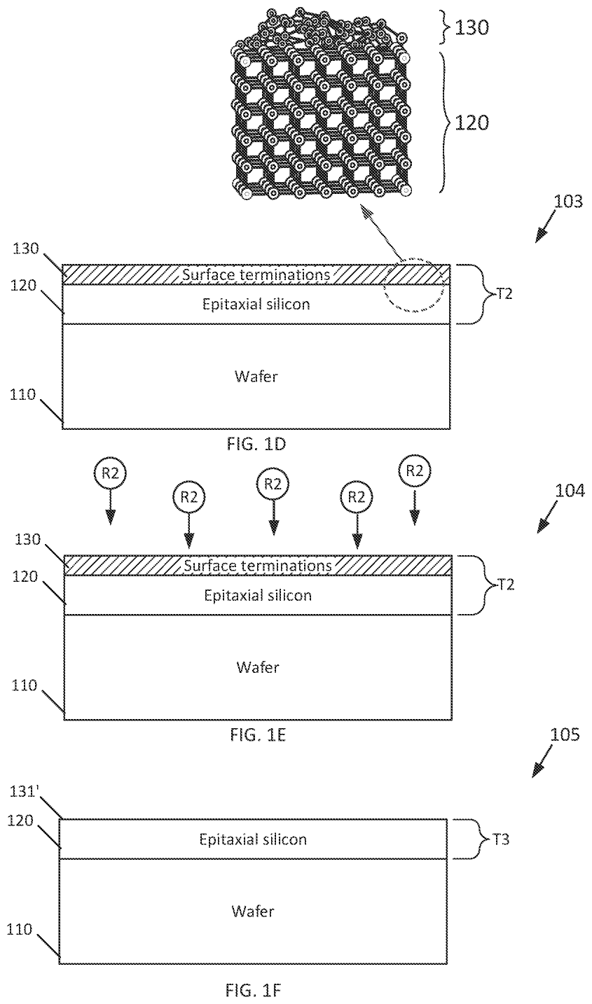

As discussed above and in a manner such as illustrated in the inset of FIG. 1D, the bulk 120 of the epitaxially grown silicon may be substantially ordered, e.g., may be substantially crystalline with a well-defined crystallographic orientation. However, the surface 130 of the epitaxially grown silicon may include random surface terminations. The surface terminations may include two or more of silicon moieties, hydrogen moieties, chlorine moieties, phosphorous moieties, arsenic moieties, or combinations thereof. For example, FIG. 2 schematically illustrates examples of surface terminations on an epitaxially grown silicon film, e.g., prior to processing using radicals in a manner such as provided herein. Terminations may include any combination of two or more of hydrogen moieties (e.g., H), silicon moieties (e.g., SiClH₂, SiCl₂H, SiH₃, SiH₂, Si(PH₂)H₂, and/or Si(AsH₂)H₂), chlorine moieties (e.g., Cl), phosphorous moieties (e.g., PH₂ and/or Si(PH₂)H₂), and/or arsenic moieties (e.g., AsH₂). As noted above, such moieties may be randomly distributed across the surface, and may promote oxidation and/or charge trap states that reduce the quality of the film and of any devices using such film.

As provided herein, a radical species may be used to remove such random surface terminations from the surface 130 of the epitaxially grown silicon film and to generate a substantially uniform distribution of surface terminations. For example, at operation 104 illustrated in FIG. 1E, the structure including wafer 110, bulk epitaxial silicon 120, and surface terminations 130 is exposed to a second radical species R2, e.g., in a different reaction chamber than in which operations 102 and 103 are performed, and optionally in the same reaction chamber in which operations 100 and 101 are performed. The second radical species R2 partially or substantially removes surface terminations 130. In particular, second radical species R2 may react preferentially with the random surface terminations as compared to a bulk of the silicon film. Some of the products of the reaction with second radical species R2 may be gaseous, while others may become bound to the epitaxial silicon to form a relatively uniform distribution of surface terminations that remain on the epitaxial silicon. At operation 105 illustrated in FIG. 1F, the second radical species then is removed, for example using a flow of an inert gas. As illustrated in FIG. 1F, following use of second radical species R2, the random surface terminations 130 are substantially removed, providing epitaxial silicon 120 including surface 131′ and having a reduced thickness T3 which is less than T2. Surface 131′ may include a substantially uniform distribution of surface terminations which substantially include, and indeed may consist essentially of, reaction products of the second radical species R2 with silicon, such as Si—H), Si—Cl, Si—F, or Si—N.

The second radical species R2 preferentially may react with the random surface terminations as compared to the bulk of the silicon film. For example, such random surface terminations may be of higher energy than the remainder of silicon film 120. Illustratively, silicon 100 is higher energy than silicon 111, and R2 therefore may react with the silicon 100 preferentially to the silicon 111. Etching higher energy surfaces is advantageous for ensuring the grown crystal adopts a self-limiting shape. A self-limiting crystal in epitaxy is one which has substantially only Si 111 planes at the surface. Moreover, etching higher energy surfaces may lead to less near surface defectivity. Accordingly, in some examples processed surface 131′ may consist essentially of a single crystallographic orientation (e.g., Si 111 and/or the same crystallographic orientation as silicon film 120) and may include a substantially uniform distribution of surface terminations. Surface 131′ may be substantially devoid of any random surface terminations.

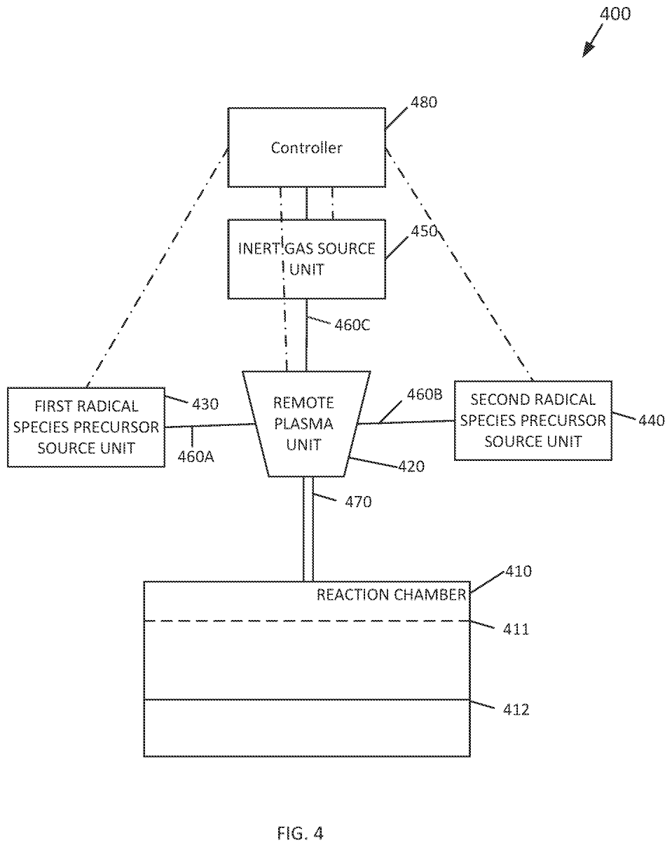

In examples that include epitaxially growing silicon film 120, any suitable first radical species R1 may be used that substantially removes the oxide from wafer 110 during operation 100, and the first radical species may be generated in any suitable manner. In nonlimiting examples such as described with reference to FIG. 4, the first radical species R1 may be generated using a first radical precursor and a remote plasma unit that generates the first radical species using the first radical precursor.

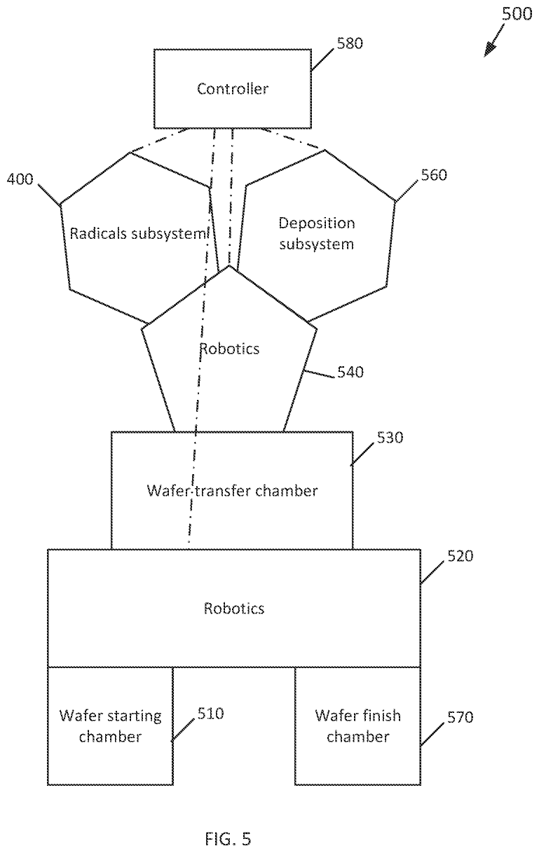

Additionally, in examples that include epitaxially growing silicon film 120, any suitable precursor(s) may be used that form such a film. For example, as described with reference to FIG. 5, the film may be formed using any suitable deposition subsystem known in the art. Illustratively, a silicon precursor (e.g., SiCl₄, dichlorosilane, silane, disilane, or trisilane) is passed across the wafer surface in the presence of an inert carrier gas. Dopant precursors concomitantly pass over the wafer surface. The combination of precursor flows, temperature and pressure cause growth of the epitaxial film.

Any suitable second radical species R2 may be used that removes random surface terminations from the surface of the epitaxially grown silicon film and generates a substantially uniform distribution of surface terminations, and the second radical species may be generated in any suitable manner. In some examples, the first and second radical species may be the same as one another. As such, the second radical species R2 may be generated using the same precursor and remote plasma unit as the first radical species R1. In other examples such as described with reference to FIG. 4, the second radical species R2 may be generated using a second radical precursor and a remote plasma unit that generates the second radical species using the second radical precursor.

In some examples, first radical species R1 and/or second radical species R2 includes a fluorine, chlorine, nitrogen or hydrogen radical. In some examples, the fluorine radical may be generated using a nitrogen trifluoride (NF₃) precursor which forms NF₂ radical, or HF precursor which forms F radical. The chlorine radical may be generated using chlorine (Cl₂) which forms Cl radical. The nitrogen radical may be generated using ammonia (NH₃) which forms NH₂ radical. The hydrogen radical may be generated using hydrogen (H₂).

It will be appreciated that any suitable system(s) may be used to process the epitaxially grown silicon film using a radical species. In some examples, wafer 110 may be located within the same chamber during use of the first radical species R1 and during use of the second radical species R2. That is, wafer 110 need not necessarily be located in one chamber during use of first radical species R1 and located in a different chamber for use of second radical species R2. Instead, operations 100, 101, 104, and 105 described with reference to FIGS. 1A-1B and 1E-1F all may be performed in the same chamber as one another, thus providing a streamlined flow of operations for processing the wafer surface. Operations 102 and 103 to epitaxially grow a silicon film on wafer 110 may be performed in a different chamber than the radical-based operations, and the wafer suitably transferred between the chambers between use of the first and second radical species.

FIG. 4 schematically illustrates components of an example system for processing the surface of an epitaxially grown silicon film using a radical species. System 400 illustrated in FIG. 4 may include reaction chamber 410; remote plasma unit 420; first radical species precursor source unit 430; second radical species precursor source unit 440; inert gas source unit 450; a series of gas lines 460A-260C respectively coupling the first radical species precursor source unit, second radical species precursor source unit, and inert gas source unit to remote plasma unit 420; a main gas line 470 coupling remote plasma unit 420 to reaction chamber 410; and controller 480.

Controller 480 may be operably coupled to the first radical species precursor source unit 430, the second radical species precursor source unit 440, the inert gas source unit 450, and the remote plasma unit 420 (such electrical connections being illustrated in dash-dot lines). Controller 480 may be configured to control so as to implement operations 100, 101, 104, and 105 described with reference to FIGS. 1A-1B and 1E-1F. For example, controller 480 may be configured to as to cause first radical species precursor source unit 430 to flow the first radical species precursor through gas line 460A and to cause the inert gas source unit to flow the inert gas through gas line 460C into remote plasma unit 420. Controller 480 also may be configured so as to cause the remote plasma unit 420 to ignite the resulting mixture of gases to form a plasma including first radical species R1, and to flow the first radical species through main gas line 470 to reaction chamber 410 so as to implement operation 100 described with reference to FIG. 1A. Controller 480 further may be configured to cause the inert gas source unit to flow the inert gas into remote plasma unit 420, and to cause the remote plasma unit 420 to flow the inert gas through main gas line 470, without igniting a plasma, to reaction chamber 410 so as to implement operation 101 described with reference to FIG. 1B after operation 100 is complete. Note that use of first radical species R1, implementation of operations 100 and 101, and use of first radical species precursor source unit 430 may be omitted from implementations in which the epitaxially grown silicon film has separately been provided.

Controller 480 further may be configured to as to cause second radical species precursor source unit 440 to flow the second radical species precursor through gas line 460B and to cause the inert gas source unit to flow the inert gas through gas line 460C into remote plasma unit 420. Controller 480 also may be configured so as to cause the remote plasma unit 420 to ignite the resulting mixture of gases to form a plasma including second radical species R2, and to flow the second radical species through main gas line 470 to reaction chamber 410 so as to implement operation 104 described with reference to FIG. 1E upon the epitaxially grown silicon film 120 including surface terminations 130. Controller 480 further may be configured to cause the inert gas source unit to flow the inert gas into remote plasma unit 420, and to cause the remote plasma unit 420 to flow the inert gas through main gas line 470, without igniting a plasma, to reaction chamber 410 so as to implement operation 105 described with reference to FIG. 1F after operation 104 is complete.

Reaction chamber 410 may include stage 412 configured to hold wafer 410, and flow regulator 411 configured to provide for relatively even flow of gases to the surface of the wafer during operations 100, 101, 104, and 105.

It will be understood that components of system 400 described with reference to FIG. 4 optionally may be incorporated into larger systems that are configured to perform one or more additional operations using the wafer surface provided herein. For example, FIG. 5 schematically illustrates components of an example system for depositing an epitaxially grown silicon film and for processing the surface of that film using a radical species. System 500 includes radicals subsystem 400 which may correspond to system 400 described with reference to FIG. 4, and controller 580 which may correspond to controller 480 described with reference to FIG. 4 but with additional functionality so as to control additional subsystems. For example, system 500 may include wafer starting chamber 510; robotics 520; wafer transfer chamber 530; robotics 540; deposition subsystem 560; and wafer finish chamber 570. Controller 580 may be operably coupled to radicals subsystem 400, robotics 520, robotics 540, and deposition subsystem 560 (such electrical connections being illustrated in dash-dot lines).

Wafer starting chamber 510 may be configured to receive any suitable number of semiconductor wafers for processing. Controller 580 may be configured to cause robotics 520 to move wafer(s) from wafer starting chamber 510 to wafer transfer chamber 530. Controller 580 also may be configured to cause robotics 540 to move wafer(s) from wafer transfer chamber 530 to radicals subsystem 400 for processing such as described with reference to FIGS. 1A-1B and 4. Controller 580 also may be configured to cause robotics 540 to move wafer(s) from radicals subsystem 400 to deposition subsystem 560 for epitaxially growing a silicon film on the processed wafer in a manner such as described with reference to FIGS. 1C-1D. In one nonlimiting example, deposition subsystem 560 is configured to epitaxially grow a silicon film on the processed wafer. Controller 580 also may be configured to cause robotics 540 to move wafer(s) from deposition subsystem 560 back to radicals subsystem 400 for processing such as described with reference to FIGS. 1E-1F and 4. Controller 580 also may be configured to cause robotics 540 to move wafer(s) from radicals subsystem 400 to wafer transfer chamber 530. Controller 580 also may be configured to cause robotics 520 to move wafer(s) from wafer transfer chamber 530 to wafer finish chamber 570.

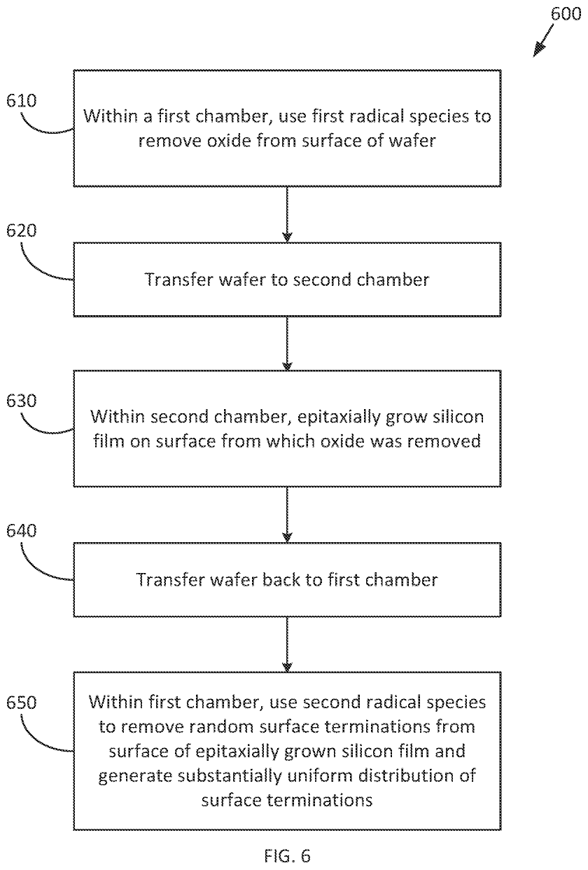

It will be appreciated that systems 400 and 500 provide nonlimiting examples of hardware and software that may be used to process wafers in the manner provided herein. For example, FIG. 6 illustrates a flow of operations in an example method for processing the surface of an epitaxially grown silicon film using a radical species. Method 600 illustrated in FIG. 6 may include, within a first chamber, using a first radical species to remove oxide from the surface of a wafer (operation 610), e.g., in a manner such as described with reference to operation 100 of FIG. 1A. For example, radicals subsystem 400 may expose the wafer to the first radical species in a manner such as described with reference to FIG. 5. Method 600 illustrated in FIG. 6 also may include transferring the wafer to a second chamber (operation 620). For example, robotics 540 may transfer the wafer from radical subsystem 400 to deposition subsystem 560 in a manner such as described with reference to FIG. 5. Method 600 illustrated in FIG. 6 also may include, within the second chamber, epitaxially growing a silicon film on the surface from which the oxide was removed (operation 630), e.g., in a manner such as described with reference to operation 102 of FIG. 1C. For example, deposition subsystem 560 may expose the wafer to precursor(s) in a manner such as described with reference to FIG. 5. Method 600 illustrated in FIG. 6 also may include transferring the wafer back to the first chamber (640). For example, robotics 540 may transfer the wafer from deposition subsystem 560 back to radical subsystem 400 in a manner such as described with reference to FIG. 5. Method 600 illustrated in FIG. 6 may include, within the first chamber, using a second radical species to remove random surface terminations from the surface of the epitaxially grown silicon film and generate a substantially uniform distribution of surface terminations (operation 650), e.g., in a manner such as described with reference to operation 104 of FIG. 1E. For example, radicals subsystem 400 may expose the wafer to the second radical species in a manner such as described with reference to FIG. 5.

It will be appreciated that operation 650 suitably may be performed on any epitaxially grown silicon film, and that the film need not necessarily be grown within the context of method 600. That is, the epitaxially grown silicon film may be obtained from any suitable source, and operation 650 then performed thereon. In this regard, the use of the terms “first” and “second” are not intended to suggest that both such elements or operations need to be used.

Wafer 110, which may be used in operations 100-103 or 610-650 and in systems 400 or 500, may include any suitable combination of materials. For example, wafer 110 may consist essentially of a semiconductor wafer (such as a doped or undoped silicon wafer). Or, for example, wafer 110 may include a film that is disposed on a semiconductor wafer. Epitaxially grown silicon film 120 may be horizontally oriented (e.g., substantially parallel to the major surface of wafer 110), or may be vertically oriented (e.g., substantially perpendicular to the major surface of wafer 110). Wafer 110, epitaxially grown silicon film 120, and/or any other films that may be disposed on the wafer may be patterned.

For example, epitaxially grown silicon film 120 may include a component of a FINFET or a storage node capacitor for DRAM. In FINFET source/drain applications, there are particularly high standards for the quality of epitaxial silicon crystal growth on top of the fin structure. Even though a given process may produce good crystal quality, there often exist circumstances wherein the grown will proceed faster on one fin over another. This difference in growth rate may make it such that fins may grow together via the source/drain epitaxially grown silicon film. Alternatively, a situation may arise where one fin has little deposition, and another has superfluous deposition. Such growth rate differences may arise from random variation in the fin starting surfaces.

Etch back previously has been used to etch away higher energy surfaces from fins, leaving behind crystalline silicon. Etch backs can be tailored to be more or less aggressive, and can be used to tune the thickness profile locally. However, the chemicals used in etch back, such as HCl or Cl₂, can have undesirably long lifetimes. Additionally, such chemicals may easily diffuse into the silicon film because their size is relatively small compared to the silicon crystal lattice. If an etchant moves into the silicon subsurface, then crystal quality of the subsurface may be negatively affected; for example, silicon may locally lose its diamond geometry by Si—Cl covalent bonding. Such bonding may negatively affect the electrical performance of the silicon film. Chemical etchants also may leach out dopants from epitaxially grown silicon films.

As provided herein, as an alternative to etching, radical species may be used to shape fins, e.g., by removing random surface terminations from the fins. Such radical species may not readily diffuse into the silicon crystal lattice, e.g., because they are too large and/or because they are so reactive that they react or recombine before substantial diffusion into the subsurface may occur. As such, the radical species substantially may not affect the crystal quality of the subsurface, nor leach out chemical etchants. Indeed, the radical species may improve the electrical performance of the silicon film by removing random surface terminations from the fins which otherwise may facilitate oxidation or provide charge trap sites in a manner such as described elsewhere herein.

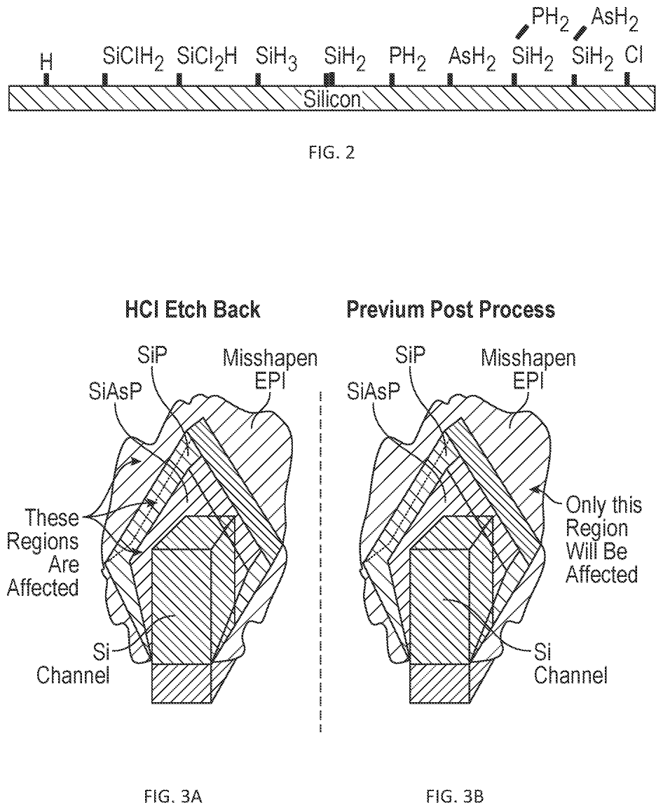

FIGS. 3A-3B schematically illustrate example films disposed on epitaxially grown silicon films respectively without, and with, the present processing. As illustrated in FIG. 3A, HCl etch back may affect not only misshapen epitaxially grown silicon (having random surface terminations and/or higher energy crystal planes), but also may affect regions that are doped with P or with AsP. In comparison, as illustrated in FIG. 3B, the present radical species may be expected to affect substantially only the misshapen epitaxially grown silicon (having random surface terminations). For example, in the case of correcting misshapen epitaxial films, less reactive species may be particularly suitable, such as chlorine or hydrogen radicals, which may sample more of the film's surface before reacting thus promoting substantially uniform surface terminations.

It will be appreciated that controller 480 may be implemented using any suitable combination of digital electronic circuitry, integrated circuitry, application specific integrated circuits (ASICs), field programmable gate arrays (FPGAs), central processing units (CPUs), graphical processing units (GPUs), computer hardware, firmware, software, and/or combinations thereof. For example, one or more functionalities of controller 480 may be implemented in one or more computer programs that are executable and/or interpretable on a programmable system including at least one programmable processor, which can be special or general purpose, coupled to receive data and instructions from, and to transmit data and instructions to, a storage system, at least one input device, and at least one output device. The programmable system or computing system can include clients and servers. A client and server are generally remote from each other and typically interact through a communication network. The relationship of client and server arises by virtue of computer programs running on the respective computers and having a client-server relationship to each other.

These computer programs, which can also be referred to as modules, programs, software, software applications, applications, components, or code, can include machine instructions for a programmable processor, and/or can be implemented in a high-level procedural language, an object-oriented programming language, a functional programming language, a logical programming language, and/or in assembly/machine language. As used herein, the terms “memory” and “computer-readable medium” refer to any computer program product, apparatus and/or device, such as magnetic discs, optical disks, solid-state storage devices, memory, and Programmable Logic Devices (PLDs), used to provide machine instructions and/or data to a programmable data processor, including a machine-readable medium that receives machine instructions as a computer-readable signal. The term “computer-readable signal” refers to any signal used to provide machine instructions and/or data to a programmable data processor. The computer-readable medium can store such machine instructions non-transitorily, such as would a non-transient solid-state memory or a magnetic hard drive or any equivalent storage medium. The computer-readable medium can alternatively or additionally store such machine instructions in a transient manner, such as for example as would a processor cache or other random access memory associated with one or more physical processor cores.

The computer components, software modules, functions, data stores and data structures can be connected directly or indirectly to each other in order to allow the flow of data needed for their operations. It is also noted that a module or processor includes but is not limited to a unit of code that performs a software operation, and can be implemented for example as a subroutine unit of code, or as a software function unit of code, or as an object (as in an object-oriented paradigm), or as an applet, or in a computer script language, or as another type of computer code. The software components and/or functionality can be located on a single computer or distributed across multiple computers and/or the cloud, depending upon the situation at hand.

In one nonlimiting example, controller 480 described with reference to FIGS. 4-5 may be implemented using a computing device architecture. In such architecture, a bus (not specifically illustrated) can serve as the information highway interconnecting the other illustrated components of the hardware. The system bus can also include at least one communication port (such as a network interface) to allow for communication with external devices either physically connected to the computing system or available externally through a wired or wireless network. Controller 480 may be implemented using a CPU (central processing unit) (e.g., one or more computer processors/data processors at a given computer or at multiple computers) that can perform calculations and logic operations required to execute a program. Controller 480 may include a non-transitory processor-readable storage medium, such as read only memory (ROM) and/or random access memory (RAM) in communication with the processor(s) and can include one or more programming instructions for the operations provided herein, e.g., for implementing methods 500 and/or 600. Optionally, the memory may include a magnetic disk, optical disk, recordable memory device, flash memory, or other physical storage medium. To provide for interaction with a user, controller 480 may include or may be implemented on a computing device having a display device (e.g., a CRT (cathode ray tube) or LCD (liquid crystal display) monitor) for displaying information obtained to the user and an input device such as keyboard and/or a pointing device (e.g., a mouse or a trackball) and/or a touchscreen by which the user can provide input to the computer.

The example embodiments of the disclosure described above do not limit the scope of the invention, since these embodiments are merely examples of the embodiments of the invention, which is defined by the appended claims and their legal equivalents. Any equivalent embodiments are intended to be within the scope of this invention. Indeed, various modifications of the disclosure, in addition to those shown and described herein, such as alternative useful combination of the elements described, may become apparent to those skilled in the art from the description. Such modifications and embodiments are also intended to fall within the scope of the appended claims.

What is claimed is:

1. A method of processing a surface of an epitaxially grown silicon film, the method comprising:
using a first radical species to remove random surface terminations from the surface of the epitaxially grown silicon film and to generate a substantially uniform distribution of surface terminations.

2. The method of claim 1, wherein the first radical species reacts preferentially with the random surface terminations as compared to a bulk of the epitaxially grown silicon film.

3. The method of claim 1, wherein the first radical species comprises a hydrogen radical, and wherein the substantially uniform distribution of surface terminations comprises Si—H moieties.

4. The method of claim 1, wherein the first radical species comprises a chlorine radical, and wherein the substantially uniform distribution of surface terminations comprises Si—Cl moieties.

5. The method of claim 1, wherein the first radical species comprises a fluorine radical, and wherein the substantially uniform distribution of surface terminations comprises Si—F moieties.

6. The method of claim 1, wherein the first radical species comprises a nitrogen radical, and wherein the substantially uniform distribution of surface terminations comprises Si—N moieties.

7. The method of claim 1, wherein the random surface terminations comprise combinations of two or more of silicon moieties, hydrogen moieties, chlorine moieties, phosphorous moieties, and arsenic moieties.

8. The method of claim 1, wherein the first radical species forms covalent bonds with the surface.

9. The method of claim 1, further comprising using a second radical species to clean a wafer before forming the epitaxially grown silicon film on the wafer.

10. The method of claim 9, wherein the wafer is located within the same chamber during use of the second radical species to clean the wafer and during use of the radical species to remove the random surface terminations from the surface of the epitaxially grown silicon film.

11. A film deposition method, comprising:
within a first chamber, using a first radical species to remove an oxide from a surface of a wafer;
transferring the wafer to a second chamber;
within the second chamber, epitaxially growing a silicon film on the surface from which the oxide was removed;
transferring the wafer, having the epitaxially grown silicon film thereon, back to the first chamber; and
within the first chamber, using a second radical species to remove random surface terminations from the surface of the epitaxially grown silicon film and to generate a substantially uniform distribution of surface terminations.

12. The method of claim 11, wherein the transferring operations are performed using robotics.

13. The method of claim 12, wherein the robotics transfer the wafer from the first chamber to the second chamber through a transfer chamber, and from the second chamber to the first chamber through the transfer chamber.

14. The method of claim 11, wherein the second radical species reacts preferentially with the random surface terminations as compared to a bulk of the epitaxially grown silicon film.

15. The method of claim 11, wherein the second radical species comprises a hydrogen radical, and wherein the substantially uniform distribution of surface terminations comprises Si—H moieties.

16. The method of claim 11, wherein the second radical species comprises a chlorine radical, and wherein the substantially uniform distribution of surface terminations comprises Si—Cl moieties.

17. The method of claim 11, wherein the second radical species comprises a fluorine radical, and wherein the substantially uniform distribution of surface terminations comprises Si—F moieties.

18. The method of claim 11, wherein the second radical species comprises a nitrogen radical, and wherein the substantially uniform distribution of surface terminations comprises Si—N moieties.

19. The method of claim 11, wherein the random surface terminations comprise combinations of two or more of silicon moieties, hydrogen moieties, chlorine moieties, phosphorous moieties, and arsenic moieties.

20. The method of claim 11, wherein the second radical species forms covalent bonds with the surface.
